(19) United States
(12) Patent Application Publication
(10) Pub. No.: US 2012/0032700 A1
(43) Pub. Date: Feb. 9, 2012

(54) MULTILAYER WIRING BOARD AND METHOD FOR EVALUATING MULTILAYER WIRING BOARD

(75) Inventor: Mitsuhiko SUGANE, Kawasaki (JP)

(73) Assignee: FUJITSU LIMITED, Kawasaki-shi (JP)

(21) Appl. No.: 13/184,738

(22) Filed: Jul. 18, 2011

(30) Foreign Application Priority Data
Aug. 5, 2010 (JP) 2010-176126

(51) Int. Cl. G01R 31/28

(52) U.S. Cl. 324/763.01

(57) ABSTRACT

A method for evaluating a multilayer wiring board is provided. The multilayer wiring board includes an inner-layer on which a test pattern is disposed. The method includes arranging a plurality of first patterns and a second pattern of the test pattern such that the first patterns have a comb-like shape opposed to one another, and the second pattern has an unbranched shape extending between the opposed first patterns. A voltage is applied between the first patterns and the second pattern. An impedance of the second pattern is measured.

### CROSS-REFERENCE TO RELATED APPLICATION

This application is based upon and claims the benefit of priority of Japanese Patent Application No. 2010-176126, filed on Aug. 5, 2010, the entire contents of which are incorporated herein by reference.

### FIELD

Embodiments discussed herein are related to a multilayer wiring board and a method for evaluating a multilayer wiring board.

### BACKGROUND

In recent years, the wiring density of printed wiring boards mounted in electronic devices has become higher. In addition, in a printed wiring board in which multilayer interconnection is adopted, the thickness of interlayer insulation films has become smaller. For mounting of such a printed wiring board in an electronic device, it is necessary to evaluate the reliability of the printed wiring board in a short period of time.

Until now, a method has been used in which the reliability of a printed wiring board is evaluated by applying voltage between wires that are insulated from each other and by measuring a decrease in the insulation resistance using patterns for evaluating the reliability of printed wiring boards.

Now, a method for evaluating the reliability of printed wiring boards in the related art will be described with reference to FIG. 1. FIG. 1 is a diagram illustrating an example of patterns for evaluating the reliability of printed wiring boards in the related art. As illustrated in FIG. 1, comb-shaped test patterns 2A and 2B are formed on a printed wiring board 10. A power supply 4 is connected to the test patterns 2A and 2B.

In an evaluation method in the related art, an insulation resistance tester is connected between the test patterns 2A and 2B, and the insulation resistance between the test patterns 2A and 2B is measured. Next, voltage is applied between the test patterns 2A and 2B for a certain period of time using the power supply 4. After that, the insulation resistance tester is connected between the test patterns 2A and 2B, and the insulation resistance between the test patterns 2A and 2B is measured. In the evaluation method in the related art, the reliability of the printed wiring board 10 is evaluated by measuring the insulation resistance before and after voltage is applied between the test patterns 2A and 2B. In JP-A-2000-304801, a method is disclosed in which a test apparatus is stopped if a failure is detected during an insulation test such as that described above.

In addition, in JP-A-3-33665, a method is disclosed in which time-domain reflectometry (TDR) measurement is adopted in order to inspect conductors formed on a printed wiring board.

In the evaluation method in which comb-shaped test patterns are used, which is illustrated in FIG. 1, a point at which an insulation failure has occurred (hereinafter referred to as a “defect” or “defect point”) is visually inspected. Therefore, in the case of a laminated board in which a test pattern is provided therein, it may be difficult to inspect an insulation failure caused in a test pattern formed on the pattern layer.

In addition, even if a TDR method is performed using the comb-shaped test patterns illustrated in FIG. 1, it is difficult to locate a defect point.

### SUMMARY

According to an embodiment of the invention, a method for evaluating a multilayer wiring board is provided. The multilayer wiring board includes an inner-layer on which a test pattern is disposed. The method includes arranging a plurality of first patterns and a second pattern of the test pattern such that the first patterns have a comb-like shape opposed to one another, and the second pattern has an unbranched shape extending between the opposed first patterns. A voltage is applied between the first patterns and the second pattern. An impedance of the second pattern is measured.

Certain objects and advantages of certain embodiments of the invention will be realized and attained at least by the elements, features, and combinations particularly pointed out in the claims. It is to be understood that both the foregoing general description and the following detailed description are exemplary and explanatory, and are not restrictive of the invention.

### BRIEF DESCRIPTION OF DRAWINGS

FIG. 1 is an example of patterns for evaluating the reliability of a board in the related art.

FIG. 2 is a plan view of an example of a test pattern layer.

FIG. 3 is a plan view of an example of continuous solid pattern layers.

FIG. 4 is a plan view of an example of a through-hole connecting layer.

FIG. 5 is a sectional view illustrating the example of a layered structure including the test pattern layer.

FIG. 6 is a flowchart illustrating an example of a method for evaluating a laminated board.

FIG. 7 is a diagram illustrating a state in which a probe is connected to a board.

FIG. 8 is a diagram illustrating electrical connection in the test pattern layer in a state in which voltage is applied between a first test pattern and a second test pattern.

FIG. 9A is a diagram illustrating an example of the results of a TDR measurement in a case where an insulation failure has not occurred.

FIG. 9B is a diagram illustrating an example of the results of a TDR measurement in a case where an insulation failure has occurred.

FIG. 10 is a flowchart illustrating a method for evaluating a laminated board according to a modification.

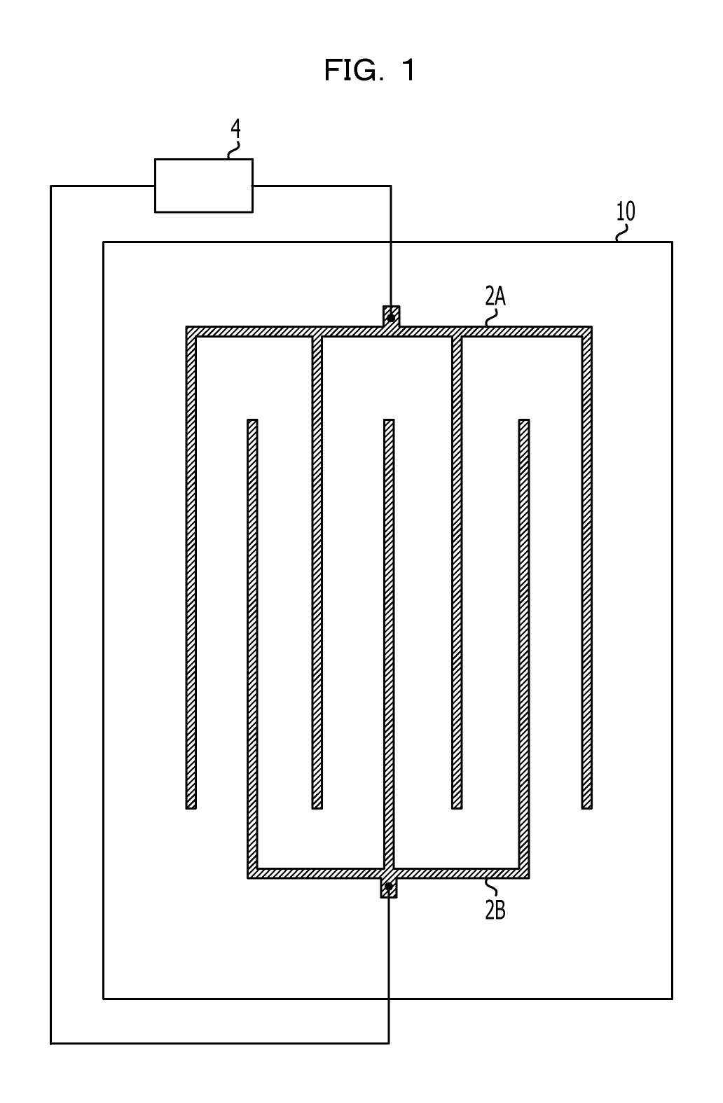

### DESCRIPTION OF EMBODIMENTS

An evaluation board used to evaluate the insulation performance of a board included in a printed wiring board, and a method for evaluating the board using the evaluation board will be described on the basis of an embodiment.

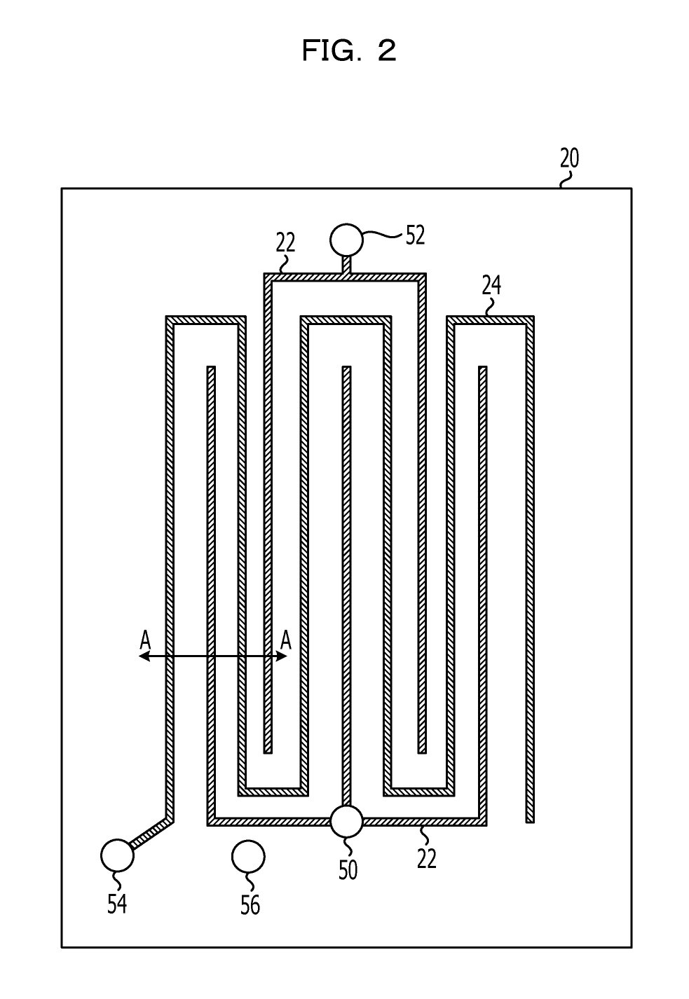

First, an evaluation board (hereinafter referred to as a “board”) will be described with reference to FIGS. 2 to 5. A board 10 according to this embodiment has a test pattern layer 20, continuous solid pattern layers 30 and 40, and a through-hole connecting layer 60. The test pattern layer 20 is disposed between the solid pattern layers 30 and 40. The layered structure of the board 10 is preferably similar to that of a product to be actually fabricated. For example, the solid pattern layers 30 and 40 are provided in order to replicate the layered structure of the product to be actually fabricated.

Now, the test pattern layer 20 according to this embodiment will be described with reference to FIG. 2. FIG. 2 is a plan view of an example of the test pattern layer 20. As illustrated in FIG. 2, the test pattern layer 20 includes first test patterns 22 that have comb-like shapes and a second test pattern 24 that is arranged between the first test patterns 22 and has no branches. In the example illustrated in FIG. 2, one of the first test patterns 22 with three teeth and the other of the first test patterns 22 with two teeth are arranged in such a way as to mesh with each other.

In addition, in the test pattern layer 20, first through holes 50 and 52, a second through hole 54, and a third through hole 56 are formed. The first through holes 50 and 52 are connected to the first test patterns 22. The second through hole 54 is connected to the second test pattern 24. The third through hole 56 is used, as described below, to electrically connect the continuous solid pattern layers 30 and 40, which sandwich the test pattern layer 20. The third through hole 56 is disposed not to be electrically connected to the first test patterns 22 or the second test pattern 24 formed on the test pattern layer 20.

Surfaces of inner walls of the first through holes 50 and 52, the second through hole 54, and the third through hole 56 are through-hole plated.

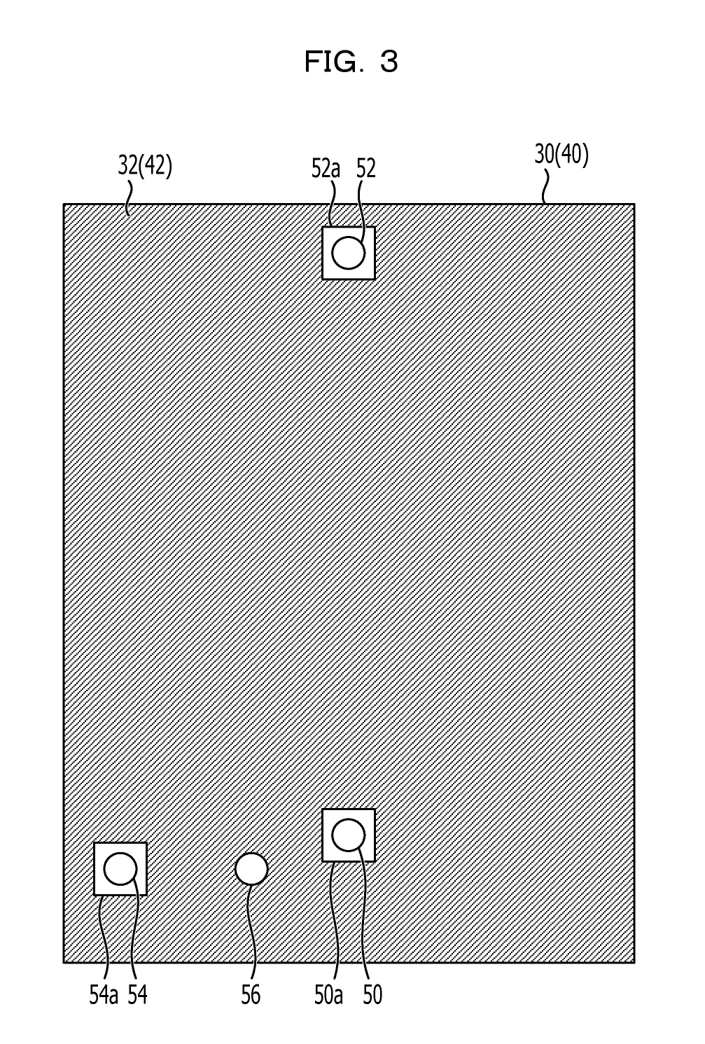

Next, the continuous solid pattern layers 30 and 40 according to this embodiment will be described with reference to FIG. 3. FIG. 3 is a plan view of an example of the solid pattern layers 30 and 40. As illustrated in FIG. 3, the first through holes 50 and 52, the second through hole 54, and the third through hole 56 are formed in the solid pattern layers 30 and 40. In addition, continuous solid pattern electrodes 32 and 42 are formed on the entire surfaces of the solid pattern layers 30 and 40, except for the first through holes 50 and 52, the second through hole 54, the third through hole 56, gaps 50a and 52a around the first through holes 50 and 52, respectively, and a gap 54a around the second through hole 54.

Around the first through holes 50 and 52, and the second through hole 54, the gaps 50a, 52a and 54a, respectively, can be provided. Therefore, the first through holes 50 and 52, and the second through hole 54 are not electrically connected to the solid pattern electrodes 32 and 42. On the other hand, no gap is provided around the third through hole 56, and therefore the third through hole 56 is electrically connected to the solid pattern electrodes 32 and 42.

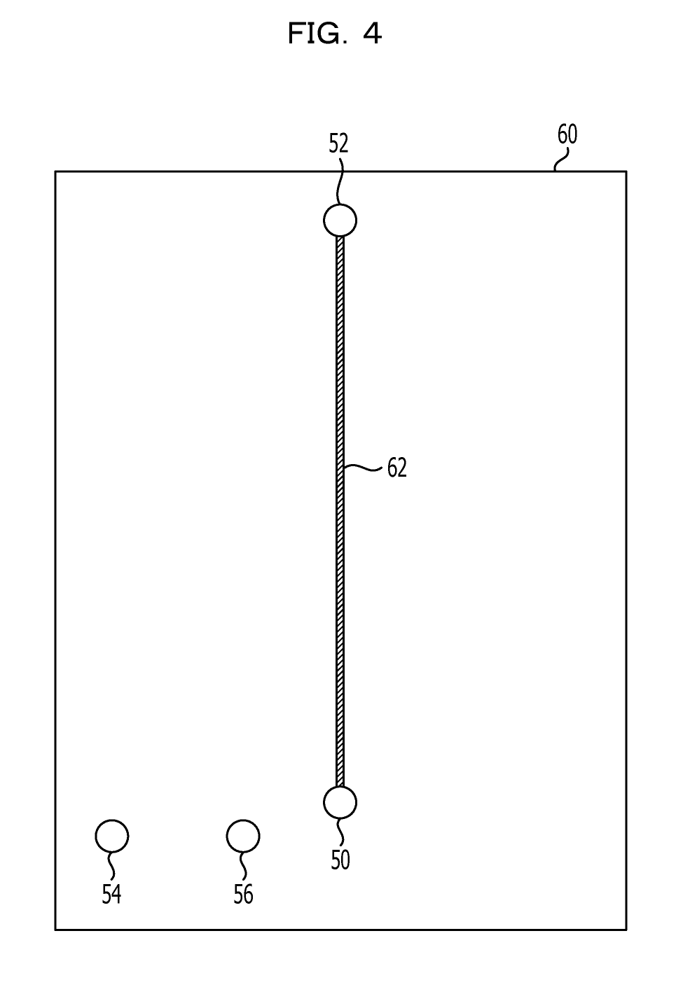

Next, the through-hole connecting layer 60 according to this embodiment will be described with reference to FIG. 4. FIG. 4 is a plan view of an example of the through-hole connecting layer 60. The position in which the through-hole connecting layer 60 is arranged is not particularly limited. For example, the through-hole connecting layer 60 may be disposed as the bottom layer of the board 10.

As illustrated in FIG. 4, in the through-hole connecting layer 60, the first through holes 50 and 52, the second through hole 54, and the third through hole 56 are formed. In addition, a wire 62 that electrically connects the first through holes 50 and 52 is also formed. As described above, since the surfaces of the inner walls of the first through holes 50 and 52 are through-hole plated, the two first test patterns 22 illustrated in FIG. 2 are electrically connected to each other through the wire 62 and the first through holes 50 and 52.

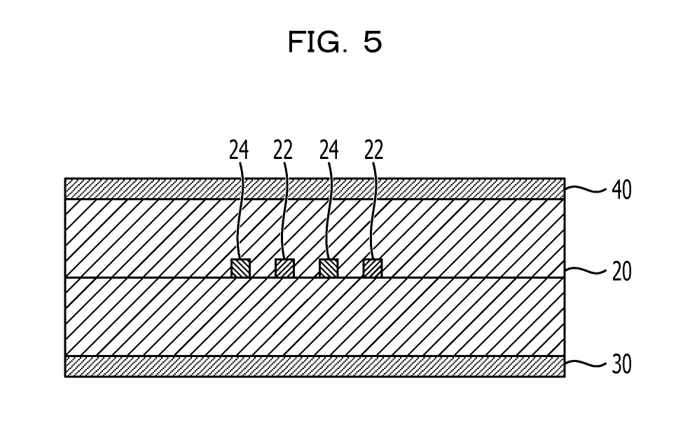

Now, the layered structure of the board 10 according to this embodiment will be described with reference to FIG. 5. FIG. 5 is a sectional view of the board 10 taken along line A-A in FIG. 2. As illustrated in FIG. 5, the test pattern layer 20 is disposed between the solid pattern layers 30 and 40. Specifically, the solid pattern layer 30 is disposed under the test pattern layer 20, and the solid pattern layer 40 is disposed over the test pattern layer 20. Although the through-hole connecting layer 60 is not illustrated in FIG. 5, the through-hole connecting layer 60 is disposed under the solid pattern layer 30.

Although the board 10 includes a single test pattern layer 20, a method for evaluating a board, which will be described below, may be applied in a case where the board 10 includes multiple test pattern layers 20.

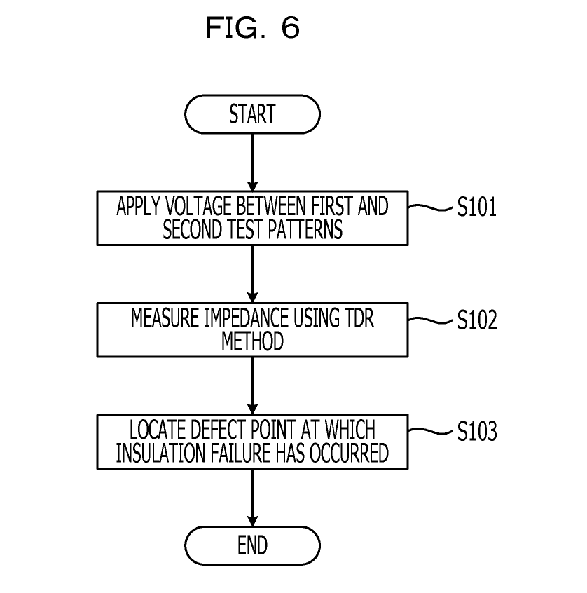

Next, a method for evaluating a board using the above-described board 10 will be described. In the method according to this embodiment, a defect in the test pattern layer 20 is located using a TDR method. Now, the outline of the method will be described with reference to FIG. 6. FIG. 6 is a flowchart illustrating an example of the method for evaluating a laminated board.

First, voltage is applied between the first test patterns 22 and the second test pattern 24 (S101). As an example of specific test conditions, a voltage of 60 V is applied between the first test patterns 22 and the second test pattern 24 for 500 hours under a temperature of 85° C. and a humidity of 85%.

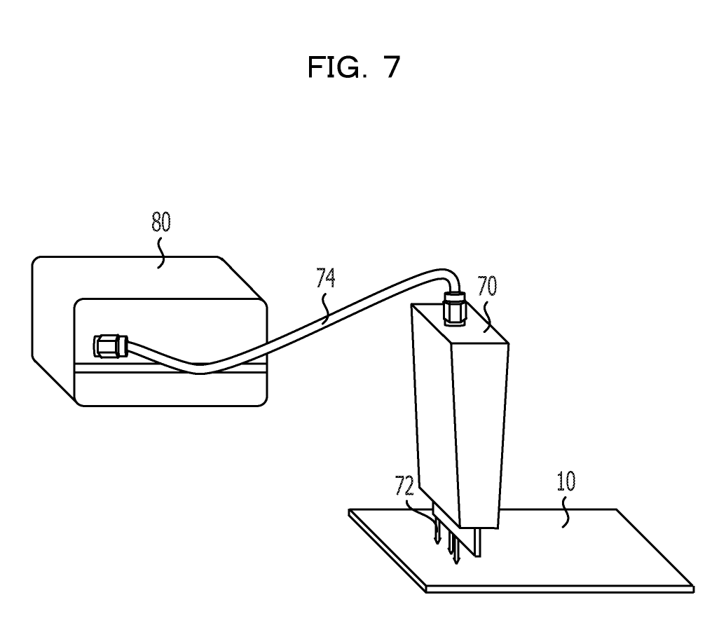

Now, a method for applying voltage between the first test patterns 22 and the second test pattern 24 will be described with reference to FIG. 7. FIG. 7 is a diagram illustrating a state in which a probe 70 is connected to the board 10. The probe 70 may have a plurality of terminals 72. The illustrated probe 70 has three terminals 72, and is connected to a test apparatus 80 with a cable 74.

The test apparatus 80 applies voltage to the terminals 72 and has a pulse generator and an oscilloscope in order to measure the impedance of the second test pattern 24 using the TDR method as described below.

The three terminals 72 are inserted into the first, second, and third through holes 50, 54, and 56, respectively, in the board 10, which has been described with reference to FIGS. 2 to 4. By applying a voltage of, for example, 60 V between one of the terminals 72 inserted into the first through hole 50 and another of the terminals 72 inserted into the second through hole 54, a voltage of 60 V is applied between the first test patterns 22 and the second test pattern 24.

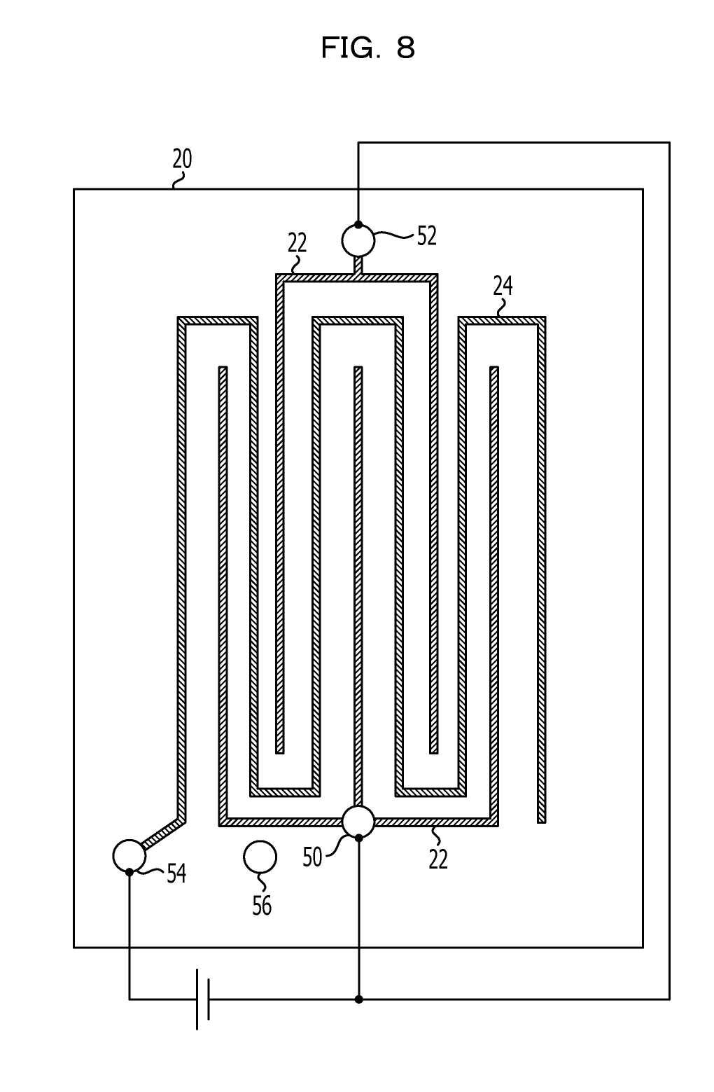

FIG. 8 is a diagram illustrating electrical connection in the test pattern layer 20 in a state where a voltage is applied between the first test patterns 22 and the second test pattern 24. As described above, the two first test patterns 22 are electrically connected to each other with the wire 62 provided on the through-hole connecting layer 60 and the first through holes 50 and 52. Therefore, by applying voltage between one of the terminals 72 inserted into the first through hole 50 and another of the terminals 72 inserted into the second through hole 54, a voltage is applied to between the first test patterns 22 and the second test pattern 24.

The description returns to FIG. 6. Next, the impedance of the second test pattern 24 is measured using the TDR method (S102). Specifically, pulse voltage is applied to one of the terminals 72 inserted into the second through hole 54 in the board 10, which has been described with reference to FIGS. 2 to 4. Since the second through hole 54 is electrically connected to an end of the second test pattern 24, the pulse voltage is applied to the end of the second test pattern 24. In addition, changes in the impedance of the second test pattern 24 are measured. A certain voltage (for example, 1 V) is supplied to one of the terminals 72 inserted into the first through hole 50 and another of the terminals 72 inserted into the third through hole 56.

Next, a location of a defect is specified based on the impedance variations measured by the TDR method (S103 of FIG. 6).

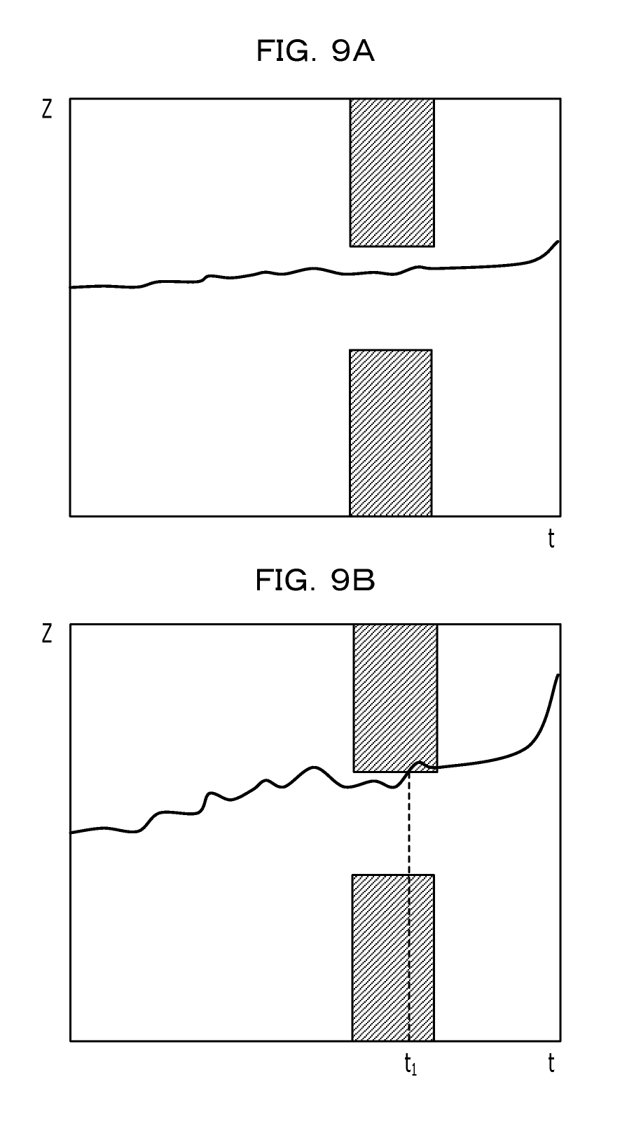

Now, changes (variations) in the impedance measured using the TDR method will be described with reference to FIGS. 9A and 9B. FIG. 9A is a diagram illustrating an example of the changes in impedance when an insulation failure has not occurred, and FIG. 9B is the changes when the insulation failure has occurred. The horizontal axes in FIGS. 9A and 9B indicate time t and the vertical axes indicate impedance Z. If the impedance curve crosses either of the shaded regions in FIGS. 9A and 9B, an insulation failure has occurred in the second test pattern 24.

Specifically, when an insulation failure has not occurred in the second test pattern 24, the value of the measured impedance is within a certain range. Therefore, as illustrated in FIG. 9A, the impedance curve does not cross the shaded regions.

On the other hand, when an insulation failure has occurred in the second test pattern 24, the value of the measured impedance is not within an acceptable range. Therefore, as illustrated in FIG. 9B, the measured impedance curve crosses either of the shaded regions.

Therefore, by measuring the impedance of the second test pattern 24 using the TDR method, it is possible to determine whether or not an insulation failure has occurred in the second test pattern 24.

Furthermore, as illustrated in FIG. 9B, when an insulation failure has occurred in the second test pattern 24, a defect in the second test pattern 24 can be located on the basis of time t₁ at which the impedance curve crosses either of the shaded regions. For example, when the impedance curve crosses either of the shaded regions in FIG. 9B at early time, it can be determined that an insulation failure has occurred at a point which is close to the second through hole 54 in the second test pattern 24 illustrated in FIG. 2. In addition, when the impedance curve crosses either of the shaded regions in FIG. 9B at late time, it can be determined that an insulation failure has occurred at a point which is far from the second through hole 54 in the second test pattern 24.

As described above, in the method for evaluating a board according to this embodiment, the insulation performance is evaluated using the second test pattern 24, which is formed on the test pattern layer 20 and has no branches. Therefore, in a case where the test pattern layer 20 is sandwiched between the solid pattern layers 30 and 40 and therefore it is difficult to visually inspect an insulation failure that has occurred in the test pattern layer 20, it is possible to locate a defect point at which the insulation failure has occurred.

Although the TDR method is used in the above-described embodiment to locate a defect in the test pattern layer 20, the method for locating a defect is not limited to the TDR method. In the following modification, another example of locating a defect will be described.

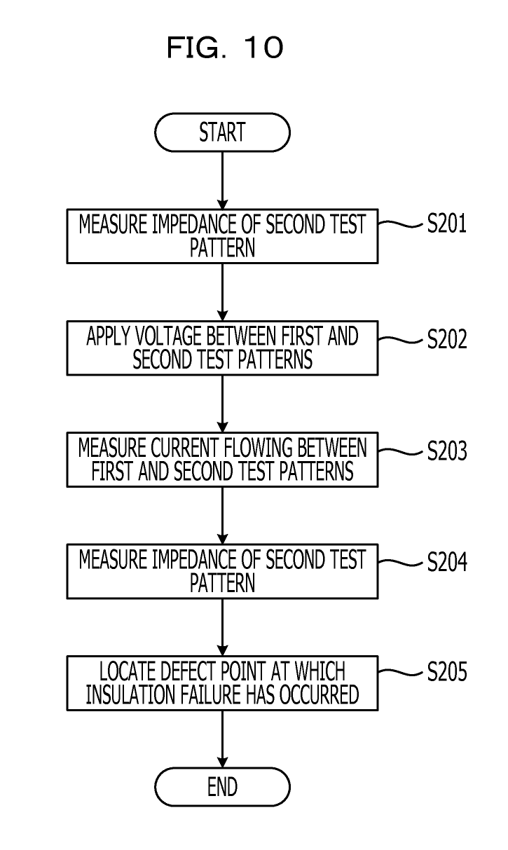

FIG. 10 is a flowchart illustrating a method for evaluating a laminated board according to a modification.

First, impedance corresponding to the distance from an end of the second test pattern 24 is measured (S201). In S201, for example, a curve can be obtained that represents the relationship between the impedance and the distance from the end of the second test pattern 24.

Next, a voltage is applied between the first test patterns 22 and the second test pattern 24 (S202). As an example of specific test conditions, a voltage of 60 V is applied between the first test patterns 22 and the second test pattern 24 for 500 hours under a temperature of 85° C. and a humidity of 85%.

In addition, at the same time as S202, current flowing between the first test patterns 22 and the second test pattern 24 is measured (S203). For example, when the insulation resistance between the first test patterns 22 and the second test pattern 24 has a normal value (for example, 100 MΩ or more), the current flowing between the first and second test patterns has a certain maximum value (for example, 0.6 μA or less).

Now, suppose that an insulation failure has occurred between the first test patterns 22 and the second test pattern 24. In this case, the insulation resistance between the first and second test patterns has a certain maximum value (for example, 100 kΩ or less), and the current flowing between the first and second test patterns has a certain maximum value (for example, 0.6 mA or more). Therefore, if the current flowing between the first and second test patterns has a certain value or a value higher than the certain value, it can be determined that an insulation failure has occurred between the first and second test patterns.

Next, as is the case with S201, impedance corresponding to the distance from an end of the second test pattern 24 is measured (S204). As a result of S204, for example, a curve can be obtained that represents the relationship between the impedance and the distance from the end of the second test pattern 24.

Next, the impedances measured in steps S201 and S204 are compared in order to locate a defect at which an insulation failure has occurred (S205). Specifically, the curves obtained in steps S201 and S204 are compared.

If no insulation failure has occurred in S202, the curves obtained in steps S201 and S204 are substantially the same. If an insulation failure has occurred in S202, when a measured point is further from the end of the second test pattern 24 than the defect point, the curves are different from each other, while the curves are substantially the same when a measured point is closer to the end of the second test pattern 24 than a defect point. Therefore, by comparing the curves obtained in steps S201 and S204, it is possible to locate a defect point at which an insulation failure has occurred.

In S203, if the value of the current flowing between the first test patterns 22 and the second test pattern 24 is within a certain range (for example, 0.6 μA or less), it can be determined that no insulation failure has occurred, and steps S204 and S205 may be omitted.

As described above, by a method in which the impedance corresponding to the distance from an end of the second test pattern 24 is measured before and after application of voltage and the impedance curves are compared as in this modification, too, it is possible to locate a defect point as in the above-described embodiment.

All examples and conditional language recited herein are intended for pedagogical objects to aid the reader in understanding the invention and the concepts contributed by the inventors to further the art, and are to be construed as being without limitation to such specifically recited examples and conditions. Although the embodiments of the invention have been described in detail, it will be understood by those of ordinary skill in the relevant art that various changes, substitutions, and alterations could be made hereto without departing from the spirit and scope of the invention as set forth in the claims.

What is claimed is:

1. A method for evaluating a multilayer wiring board including an inner-layer on which a test pattern is disposed, said method comprising:
arranging a plurality of first patterns and a second pattern of the test pattern such that the first patterns have a comb-like shape opposed to one another, and the second pattern has an unbranched shape extending between the opposed first patterns;
applying a voltage between the first patterns and the second pattern; and
measuring an impedance of the second pattern.

2. A method for evaluating a multilayer wiring board according to claim 1, wherein said applying the voltage includes applying a pulse voltage to the second pattern.

3. A method for evaluating a multilayer wiring board according to claim 1, wherein the impedance of the second pattern is measured before and after said applying voltage.

4. A method for evaluating a multilayer wiring board according to claim 3, further comprising specifying a defect location in the second pattern at which an abnormality has occurred, based on a measurement result of impedance variations of the second pattern.

5. A multilayer wiring board, comprising:
an inner-layer having a test pattern disposed thereupon, wherein the test pattern includes a plurality of first patterns having a comb-like shape opposed to one another, and a second pattern having an unbranched shape extending between the opposed first patterns.

6. A multilayer wiring board according to claim 5, further comprising:
a plurality of electrode layers interposing the test pattern therebetween.

7. A multilayer wiring board according to claim 6, further comprising:
a through-hole via through which the test pattern is electrically connected to the electrode layers.
